(19) United States
(12) Patent Application Publication
(10) Pub. No.: US 2020/0142212 A1
(43) Pub. Date: May 7, 2020

(54) STRUCTURED LIGHT EMITTER MODULE

(71) Applicant: TRIPLE WIN TECHNOLOGY(SHENZHEN) CO.LTD., Shenzhen (CN)

(72) Inventors: CHENG-AN LIN, New Taipei (TW); CHUN-YAO HUANG, New Taipei (TW)

(21) Appl. No.: 16/221,435

(22) Filed: Dec. 14, 2018

(30) Foreign Application Priority Data
Nov. 2, 2018 (CN) 201811302869.6

(51) Int. Cl. G02B 27/64; H05K 1/02; G02B 7/09; H05K 1/18

(52) U.S. Cl. CPC G02B 27/646; H05K 1/0274; H04N 5/23287; H05K 1/189; G02B 7/09

(57) ABSTRACT

A structured light emitter module includes a circuit board, a laser source, a structured light lens, an optical diffraction component, and an optical anti-shake component. The structured light lens is received within the optical anti-shake component. The optical diffraction component is mounted on the optical anti-shake component. The optical anti-shake component is mounted on a side of the structured light lens and adapted to control the structured light lens to move opposite to a direction of tilt or vibration of the structured light emitter module.

### FIELD

The subject matter herein generally relates to structured light emitter modules, and more particularly to a structured light emitter module of an electronic device.

### BACKGROUND

With the introduction of facial recognition functions, the application of structured light emitter modules has become more and more widespread, and many computer, communication, and consumer electronic products have the requirements of device structured light emitter modules.

However, when the structured light emitter module is tilted or shaken, an erroneous structured light pattern may occur which may result in a false identification.

### BRIEF DESCRIPTION OF THE DRAWINGS

Implementations of the present disclosure will now be described, by way of embodiments, with reference to the attached figures.

FIG. 1 is an assembled, isometric view of an embodiment of a structured light emitter module.

FIG. 2 is an exploded view of the structured light emitter module in FIG. 1.

FIG. 3 is a cross-sectional view of the structured light emitter module in FIG. 1 taken along line III-III.

FIG. 4 is an exploded view of an optical anti-shake component in FIG. 1.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

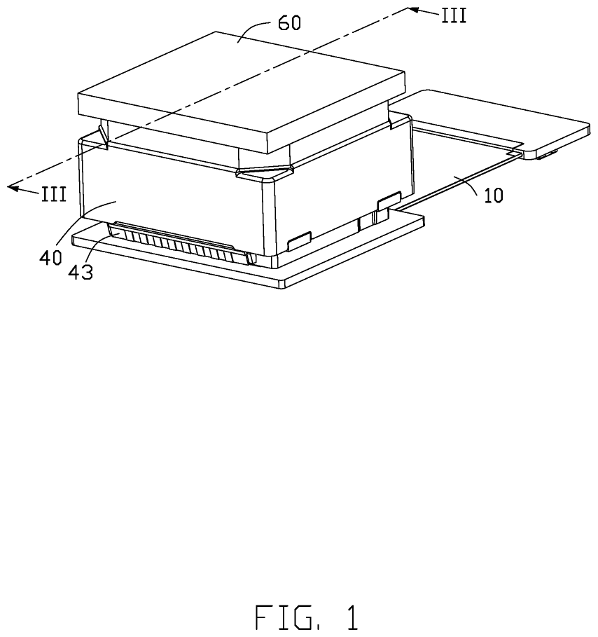

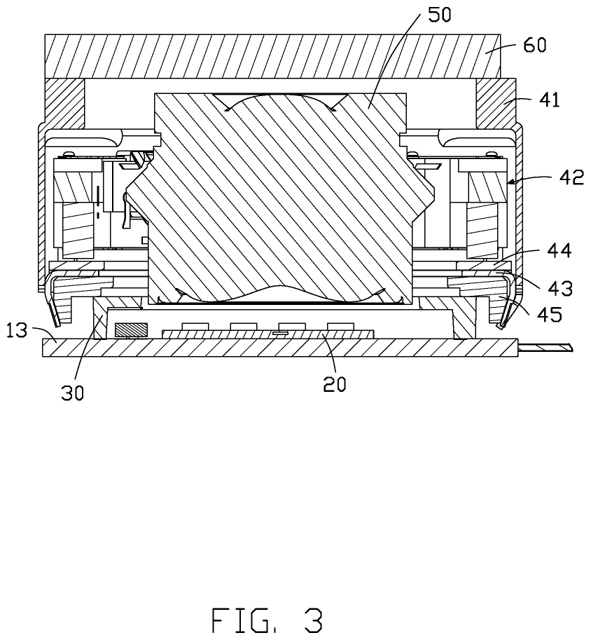

FIGS. 1-3 show an embodiment of a structured light emitter module 100 including a flexible-hard composite board 10 (hereinafter “the circuit board 10”), a laser source 20, an optical anti-shake component 40, a structured light lens 50, and an optical diffraction component 60.

The laser source 20 and the optical anti-shake component 40 are mounted on the flexible-hard composite board 10. The laser source 20 is electrically coupled to the circuit board 10 and received within the anti-shake component 40. The anti-shake component 40 is electrically coupled to the circuit board 10 and axially defines a light hole 46. The light hole 46 receives the structured light lens 50. The optical diffraction component 60 is mounted above the optical anti-shake component 40 and axially aligned with the structured light lens 50.

In operation, the circuit board 10 controls the laser source 20 to emit light. The light passes through the structured light lens 50. The structured light lens 50 collimates and expands the light. When the structured light emitter module 100 is slanted or vibrated, the optical anti-shake component 40 adjusts a position of the structured light lens 50 by moving the structured light lens 50 in an opposite direction of the slant or vibration. The collimated and expanded light beam passes through the optical diffraction component 60, and the optical diffraction component 60 scatters the light to obtain a desired speckled image.

The structured light emitter module 100 further includes a carrier 30. The carrier 30 includes a carrier surface 31 and a plurality of sidewalls 33 extending perpendicularly around a periphery of the carrier surface 31. A height of the sidewalls 33 is greater than a thickness of the laser source 20. Thus, the laser source 20 is received within the carrier 30. The optical anti-shake component 40 is mounted on the carrier surface 31. The carrier surface 31 defines a through hole 32 aligned with the light hole 46. The carrier 30 bears the optical anti-shake component 40 and increases an internal heat dissipation space of the structured light emitter module 100.

In one embodiment, the laser source 20 is a vertical-cavity surface-emitting laser.

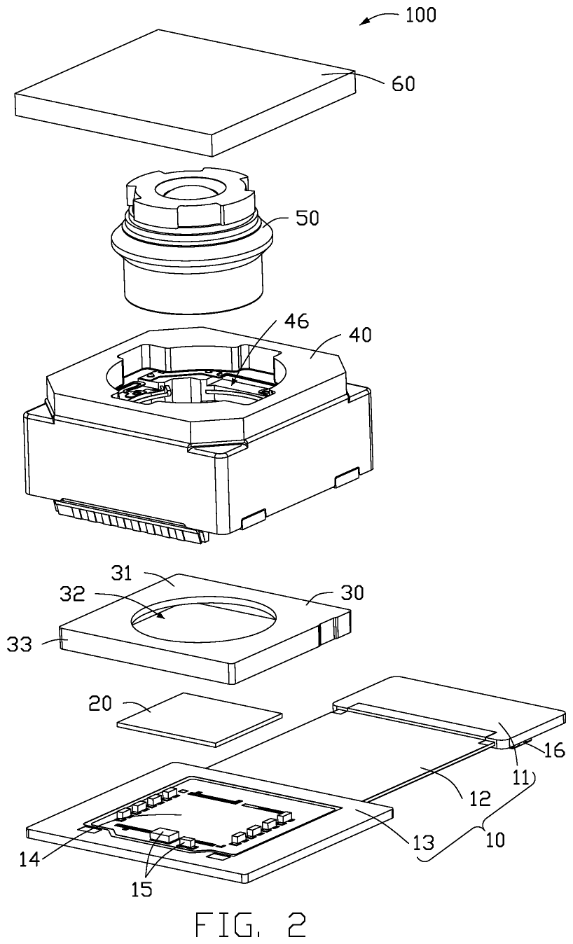

As shown in FIG. 2, the circuit board 10 includes a first hard board 11, a second hard board 13, and a flexible board 12. The flexible board 12 is coupled between the first hard board 11 and the second hard board 13. The second hard board 13 includes a central area 14 and a gyro sensing chip 15. The laser source 20 is electrically coupled to the central area 14. The gyro sensing chip 15 is electrically coupled to the circuit board 10. In other embodiments, the circuit board 10 can be a flexible board or a hard board.

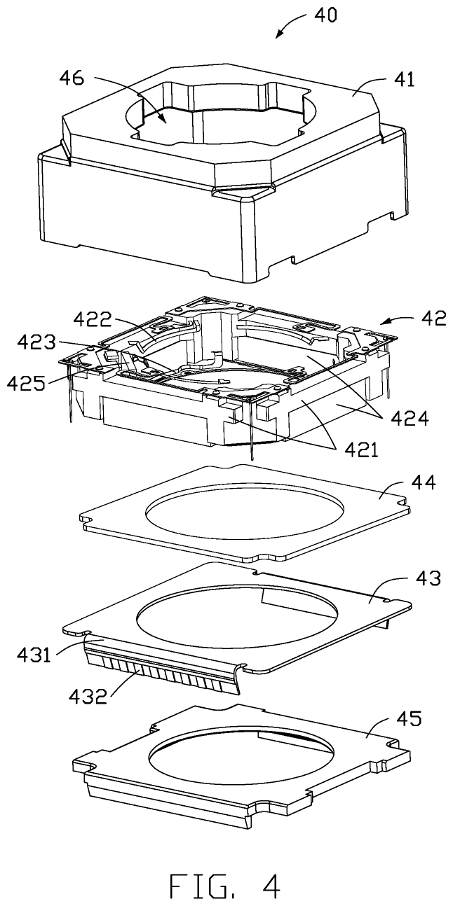

As shown in FIG. 4, the optical anti-shake component 40 includes a housing 41, a focus detection unit 42, a circuit board connector 43, an optical image stabilizer (OIS) coil 44, and a base 45.

The housing 41 is substantially hollow rectangular. The focus detection unit 42, the circuit board connector 43, the OIS coil 44, and the base 45 are received within the housing 41.

The OIS coil 44 is mounted between the focus detection unit 42 and the circuit board connector 43 and is electrically coupled to the structured light lens 50. The OIS coil 44 drives the structured light lens 40 to move.

The circuit board connector 43 is mounted between the OIS coil 44 and the base 45. The through hole 46 passes through the housing 41, the focus detection unit 42, the OIS coil 44, the circuit board connector 43, and the base 45.

The circuit board connector 43 includes a connecting layer 431 and a pair of connecting pieces 432 extending from opposite edges of the connecting layer 431 away from the focus detection unit 42. The connecting layer 431 and the connecting pieces 432 cooperatively define a receiving space 433 for receiving the base 45 therein.

The focus detection unit 42 includes a mounting frame 421, an upper clip 422, a lower clip 423, magnets 424, and an autofocus coil 425. The light hole 46 passes through the mounting frame 421. The magnets 424 are mounted within sidewalls of the mounting frame 421. The upper clip 422 extends from an inner surface of the mounting frame 421 and is resiliently deformable. The lower clip 423 extends from the inner surface of the mounting frame 421 below the upper clip 422 and is resiliently deformable. The structured light lens 50 is coupled to the upper clip 422 and the lower clip 423. The upper clip 422 and the lower clip 423 detect position information of the structured light lens 50. The autofocus coil 425 is mounted within the mounting frame 421 and drives the structured light lens 50 to autofocus.

When the autofocus coil 425 is electrically coupled to the OIS coil 44, the autofocus coil 425, the autofocus coil 425 and the OIS coil 44 receive a Lorentz force from a magnetic field generated by the magnets 424 to adjust a position of the structured light lens 50. The optical anti-shake component 40 is electrically coupled to the circuit board 10 by the circuit board connector 43 and mounted above the carrier 30 by the base 45.

In operation, as shown in FIG. 2, when the gyro sensing chip 15 detects a slant or vibration of the structured light emitter module 100, the gyro sensing chip 15 electrifies the OIS coil 44, and the electrified OIS coil 44 generates a magnetic force within the magnetic field to drive the structured light lens 50 to move in an opposite direction of the slant or vibration until the slant or vibration is offset. Simultaneously, the gyro sensing chip 15 electrifies the autofocus coil 425 to autofocus the structured light lens 50. Simultaneously, the upper clip 422 and the lower clip 423 store an adjusted position of the structured light lens 50 in a storage area of the circuit board 10. When the structured light emitter module 100 is started a next time, the gyro sensing chip 15 electrifies the OIS coil 44 and the autofocus coil 425 to restore a previous position of the structured light lens 50.

The structured light emitter module 100 is applicable in an electronic device, such as a camera. The circuit board connector 16 of the first hard board 11 can electrically couple to a motherboard of the electronic device.

The embodiments shown and described above are only examples. Even though numerous characteristics and advantages of the present technology have been set forth in the foregoing description, together with details of the structured and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A structured light emitter module comprising:
a circuit board;
a laser source mounted on the circuit board;
a structured light lens;
an optical anti-shake component mounted on the circuit board and adapted to receive the structured light lens and control the structured light lens to move opposite to a direction of tilts or vibrations of the structured light emitter module; and
an optical diffraction component mounted on the optical anti-shake component.

2. The structured light emitter module of claim 1, wherein:
the optical anti-shake component comprises an optical image stabilizer (OIS) coil adapted to control movements of the structured light lens.

3. The structured light emitter module of claim 1, wherein:
the optical anti-shake component comprises an autofocus coil adapted to focus the structured light lens.

4. The structured light emitter module of claim 2, wherein:
the optical anti-shake component comprises a circuit board connector mounted on a side of the OIS coil and adapted to electrically couple the optical anti-shake component to the circuit board.

5. The structured light emitter module of claim 4, wherein:
the optical anti-shake component comprises a base;
the circuit board connector is mounted between the base and the OIS coil.

6. The structured light emitter module of claim 5 further comprising a carrier mounted on a side of the laser source, wherein the base mounts the optical anti-shake component to the carrier.

7. An electronic device comprising a structured light emitter module comprising:
a flexible-hard composite board;
a laser source mounted to the flexible-hard composite board;
a structured light lens received within an optical anti-shake component; and
an optical diffraction component mounted on the optical anti-shake component, wherein
the optical anti-shake component is mounted on the circuit board and adapted to control the structured light lens to move opposite to a direction of tilts or vibrations of the structured light emitter module.

8. The electronic device of claim 7, wherein the optical anti-shake component comprises an OIS coil adapted to control movements of the structured light lens.

9. The electronic device of claim 7, wherein the optical anti-shake component comprises an autofocus coil adapted to focus the structured light lens.

10. The electronic device of claim 8, wherein the optical anti-shake component comprises a circuit board connector mounted on a side of the OIS coil and adapted to electrically couple the optical anti-shake component to the flexible-hard composite board.

11. The electronic device of claim 10, wherein:
the optical anti-shake component comprises a base;
the circuit board connector is mounted between the base and the OIS coil.

12. The electronic device of claim 11, wherein:
the structured light emitter module further comprises a carrier mounted on a side of the laser source;
the base mounts the optical anti-shake component to the carrier.
